(19) United States
(12) Patent Application Publication
(10) Pub. No.: US 2022/0063947 A1
(43) Pub. Date: Mar. 3, 2022

(54) CONNECTION JIG TAPE

(71) Applicant: Dongsuk Kim, Hwaseong-si (KR)

(72) Inventor: Dongsuk Kim, Hwaseong-si (KR)

(21) Appl. No.: 16/949,708

(22) Filed: Nov. 11, 2020

(30) Foreign Application Priority Data
Aug. 26, 2020 (KR) 10-2020-0107517

(51) Int. Cl. B65H 21/00

(52) U.S. Cl. CPC B65H 21/00; H01L 24/79; H01L 2224/79652

(57) ABSTRACT

Disclosed is a connection jig tape for splicing end portions of feeding tapes together, the feeding tape comprising accommodating spaces formed to accommodate electronic parts therein, a protection tape disposed on the electronic parts, and a plurality of transfer holes formed at one side thereof, the connection jig comprising: a base tape comprising projections formed to protrude from opposite sides thereof or at least two projections formed to protrude from one side thereof and spaced apart from each other to be inserted in the transfer holes of the respective feeding tapes to be spliced together; and a first splicing tape disposed on the base tape.

### CROSS-REFERENCE TO RELATED THE APPLICATION

This application is based on and claims priority under 35 U.S.C. § 119 to Korean Patent Application No. 10-2020-0107517 filed on Aug. 26, 2020 in the Korean Intellectual Property Office, the disclosure of which is incorporated by reference herein in its entirety.

### BACKGROUND

### Field

The disclosure relates to a connection jig tape, and more particularly to a connection jig tape by which feeding tapes are easily spliced together.

### Description of the Related Art

In general, an integrated circuit (IC) chip and the like electronic parts are mounted onto a circuit board through a surface mounting device such as a chip mounter.

To feed such electronic parts successively, a tape feeder is used. The tape feeder is mounted with a part drum around which a feeding tape embedded with electronic parts is wrapped in the form of a reel.

The tape feeder reels in the feeding tape from the part drum, and the electronic parts on the reeled feeding tape are mounted onto the circuit board by the chip mounter.

FIG. 1 is a plan view showing a conventional feeding tape for electronic parts. Referring to FIG. 1, a feeding tape 10 includes a plurality of accommodating spaces 12 formed at regular intervals and accommodating electronic parts 1 therein, and a protection tape 14 formed on the plurality of accommodating spaces 12 and protecting the electronic parts 1 from the outside.

Here, a plurality of transfer holes 16 are punched in one side of the feeding tape 10 along the lengthwise direction of the feeding tape 10 at regular intervals, and engaged with gear teeth of a tape feeder when the part drum is mounted to the tape feeder (not shown). Thus, the feeding tape 10 is transferred as the gear teeth turns, thereby feeding parts.

When the rolled feeding tape 10 is completely used up, there is a need of mounting a new feeding tape to the part drum. To this end, Korean Patent Publication No. 2007-0113030 has disclosed a method of connecting the old feeding tape 10 and a new feeding tape.

However, the related art has a problem that a dedicated splicing tool is needed to splice the feeding tapes together.

### SUMMARY

An aspect of the disclosure is to solve the foregoing problems, in particular, to provide a connection jig tape which is convenient to splice feeding tapes together without using a separate tool.

According to an embodiment of the disclosure, there is provided a connection jig tape for splicing end portions of feeding tapes together, the feeding tape including accommodating spaces formed to accommodate electronic parts therein, a protection tape disposed on the electronic parts, and a plurality of transfer holes formed at one side thereof, the connection jig including: a base tape including projections formed to protrude from opposite sides thereof or at least two projections formed to protrude from one side thereof and spaced apart from each other to be inserted in the transfer holes of the respective feeding tapes to be spliced together; and a first splicing tape disposed on the base tape.

The first splicing tape may include a first member corresponding to the protection tape while the projections are inserted in the transfer holes.

The first splicing tape may further include a second member formed with first position holding holes corresponding to the transfer holes of the feeding tape, and the first member and the second member may be separated from each other or connected to be cuttable.

The base tape may include a folding line, and the connection jig may further include a second splicing tape formed with a second position holding hole positioned line-symmetrically to the first position holding hole with respect to the folding line.

The second splicing tape may include a third member correspond ding to the protection tape, and a fourth member formed with the second position holding hole corresponding to the transfer hole of the feeding tape, in the state that the projection is inserted in the transfer hole and the base tape is folded with respect to the folding line.

The connection jig tape may further include a top tape disposed on the first splicing tape or the second splicing tape.

One side of the first splicing tape or the second splicing tape may be detachably adhered to the base tape, and the other side of the first splicing tape or the second splicing tape may be formed with an adhesive layer.

The base tape may at least partially include an elastic member.

### BRIEF DESCRIPTION OF THE DRAWINGS

The above and/or other aspects will become apparent and more readily appreciated from the following description of embodiments, taken in conjunction with the accompanying drawings, in which:

FIG. 1 is a plan view of a conventional feeding tape for electronic parts;

FIGS. 2A and 2B illustrate processes of splicing feeding tapes by a connection jig tape according to a first embodiment of the disclosure;

FIGS. 3A and 3B illustrate processes of splicing feeding tapes by a connection jig tape according to a second embodiment of the disclosure;

FIGS. 4A and 4B illustrate processes of splicing feeding tapes by a connection jig tape according to a third embodiment of the disclosure;

FIG. 5 illustrates processes of splicing feeding tapes by a connection jig tape according to a fourth embodiment of the disclosure; and

FIG. 6 illustrates processes of splicing feeding tapes by a connection jig tape according to a fifth embodiment of the disclosure.

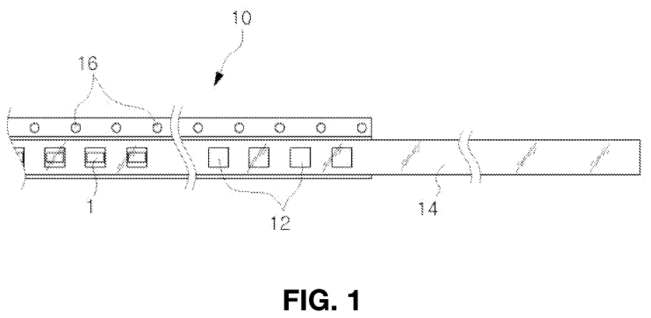

### DETAILED DESCRIPTION OF EMBODIMENTS

Below, embodiments of the disclosure will be described in detail with reference to accompanying drawings, in which the same numerals refer to the same or like elements throughout, and repetitive descriptions thereof will be avoided. In the following descriptions, suffixes for the elements, such as “part” and “device,” “module” and “part,” “unit” and “part,” and “apparatus” and “system,” etc. are given or used as mixed with each other by taking only convenience in writing the specification into account without distinct meanings or roles therebetween.

Further, detailed descriptions about publicly known art will be omitted if it is identified that they cloud the gist of the embodiment of the disclosure. Further, the accompanying drawings are merely to help easy understanding of the embodiment of the disclosure, and it will be understood that the technical concept of the disclosure is not limited by the accompanying drawings but all possible changes, equivalents and/or alternatives can be made within the concept and technical range of the disclosure.

Terms with ordinal numbers such as “first,” “second,” etc. may be used herein to describe various elements, but the elements are not limited by these terms. These terms are used only to distinguish one element from another.

It will be understood that when a certain element is referred to as being “connected” or “coupled” to another element, they can be connected or coupled each other directly or through an additional element therebetween. On the other hand, it will be understood that when a certain element is referred to as being “directly connected” or “directly coupled” to another element, they can be connected or coupled without any additional element therebetween.

Singular forms are intended to include plural forms unless otherwise mentioned contextually.

In the disclosure, a term “include,” “have,” or etc. is to indicate the presence of features, numbers, steps, operations, elements, parts or combination thereof, but does not previously exclude the presence or additionally of one or more other features, numbers, steps, operations, elements, parts or combination thereof.

Below, embodiments of the disclosure will be described in detail with reference to the accompanying drawings. It will be appreciated by those skilled in the art that alternative specific embodiments can be made without departing from the spirit and essential features of the invention.

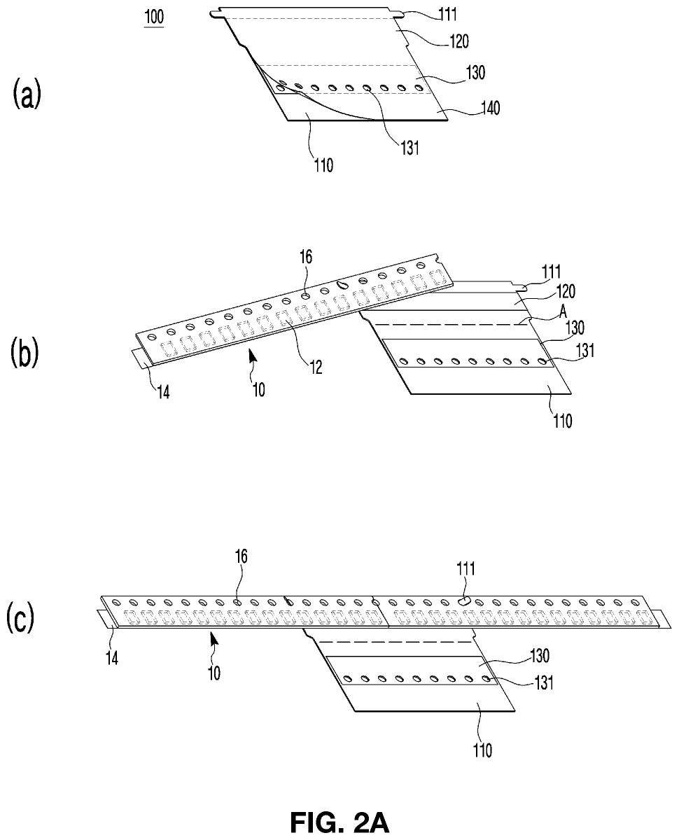

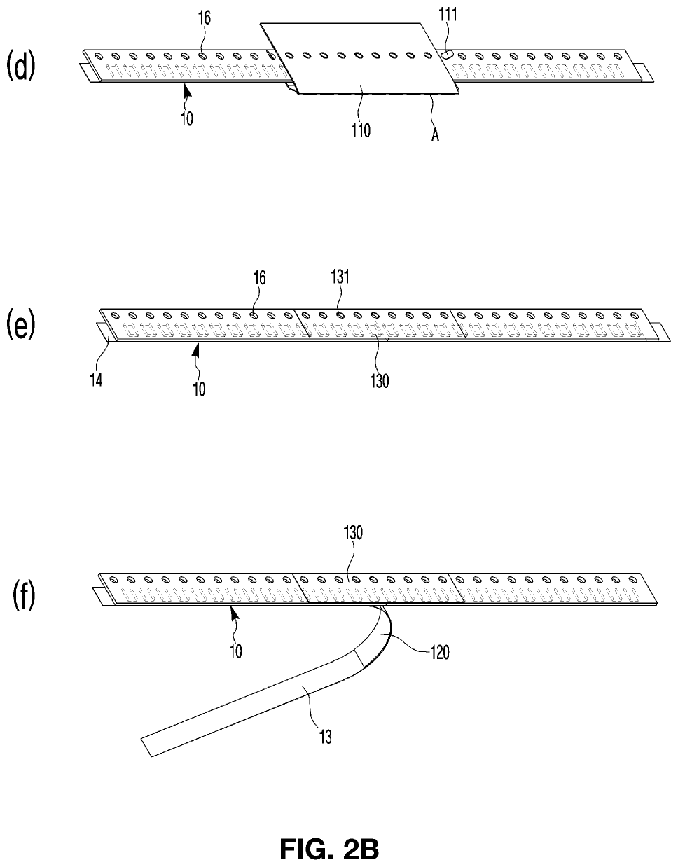

FIGS. 2A and 2B illustrate processes of splicing feeding tapes by a connection jig tape according to a first embodiment of the disclosure.

First, referring to (a) in FIG. 2A, a connection jig tape 100 according to the first embodiment of the disclosure includes a base tape 110, a first splicing tape 120 and a second splicing tape 130 disposed on the base tape 110 and spaced apart from each other, and a top tape 140 disposed on the first splicing tape 120 and the second splicing tape 130.

Here, the base tape 110 includes projections 111 respectively protruding from opposite sides thereof. The projections 111 are inserted in transfer holes 16 formed in a feeding tape 10 so as to maintain a fixed position when the feeding tapes 10 are spliced together.

Further, the second splicing tape 130 includes position holding holes 131 formed corresponding to the transfer holes 16 of the feeding tape 10.

After removing the top tape 140 disposed on the top, as shown in (b) of FIG. 2A, the projection 111 at one side of the foregoing connection jig tape 100 according to the first embodiment of the disclosure is inserted in the transfer hole 16 of one of the feeding tapes 10 to be spliced together.

Here, the feeding tape 10 is formed with quadrangular accommodating spaces 12, in which electronic parts (not shown) are accommodated, and a protection tape 14 is disposed on the electronic parts (not shown). Further, a plurality of transfer holes 16 are formed at one side of the feeding tape 10.

When one of the feeding tapes 10 is fixed being put on the projection 111 of the base tape 110, the first splicing tape 120 is positioned under the feeding tape 10. Here, the first splicing tape 120 may have a rectangular shape having a predetermined width and a predetermined length, in which the width may correspond to the width of the protection tape 14. Further, an adhesive layer is formed on a top side of the first splicing tape 120 so that an end portion of the feeding tape 10 put thereon can maintain of fixed state.

Meanwhile, the base tape 110 is formed with a folding line A between the first splicing tape 120 and the second splicing tape 130, so that the first slicing tape 120 can be used as a reference line when the second splicing tape 130 to be described later is folded to meet the first splicing tape 120.

Next, in (C) of FIG. 2A, the feeding tape 10 to be spliced is put on the other projection 111 of the base tape 110, and therefore two feeding tapes 10 are arranged in a straight line while being placed in exact positions to be spliced together by the base tape 110

Here, the base tape 110 may be made of various materials such as paper, synthetic resin, or the like which needs to have proper hardness to provisionally fix the positions of the two feeding tapes 10 when the two feeding tapes 10 are spliced together as described above. Further, the base tape 110 may be at least partially made of an elastic material. In particular, the projections 111 may be made of the elastic material because they need to be transformed and restored when being inserted in the transfer holes 16 of the feeding tape 10.

Thus, the connection jig tape 100 according to an embodiment of the disclosure holds the two feeding tapes 10, which will be spliced together by the projections 111 of the base tape 110, at exact positions through the first splicing tape 120.

Then, in (d) of FIG. 2B, the base tape 110 is folded along the folding line A. In this case, the second splicing tape 130 positioned inside the base tape 110 is folded and adhered corresponding to the feeding tape 10. Here, an adhesive layer is formed on the top of the second splicing tape 130 to thereby maintain the adhered state of the feeding tape 10.

Then, as shown in (e) of FIG. 2B, when the base tape 110 is removed, the spliced state of the feeding tapes 10 is firmly maintained as the first splicing tape 120 and the second splicing tape 130 are respectively adhered to the two feeding tapes 10. In this case, the position holding holes 131 of the second splicing tape 130 are aligned with the transfer holes 16 of the feeding tape 10. In this state, parts for surface mounting work are feedable.

Next, as shown in (f) in FIG. 2B, when parts are fed using the feeding tapes 10 spliced together, the parts may be fed while removing the protection tape 14. Although the electronic parts are not illustrated on the feeding tape 10, this is merely to avoid complexity in the drawing. Thus, it needs to be assumed that the parts for the surface mounting work are provided on the feeding tape 10.

When the protection tape 14 is removed, the first splicing tape 120 adhered on the protection tape 14 is also removed along with the protection tape 14, and the provided electronic parts (not shown) are exposed. In this case, the first splicing tape 120 is removed, but the spliced state of the feeding tape 10 is maintained by the second splicing tape 130, thereby feeding the parts successively.

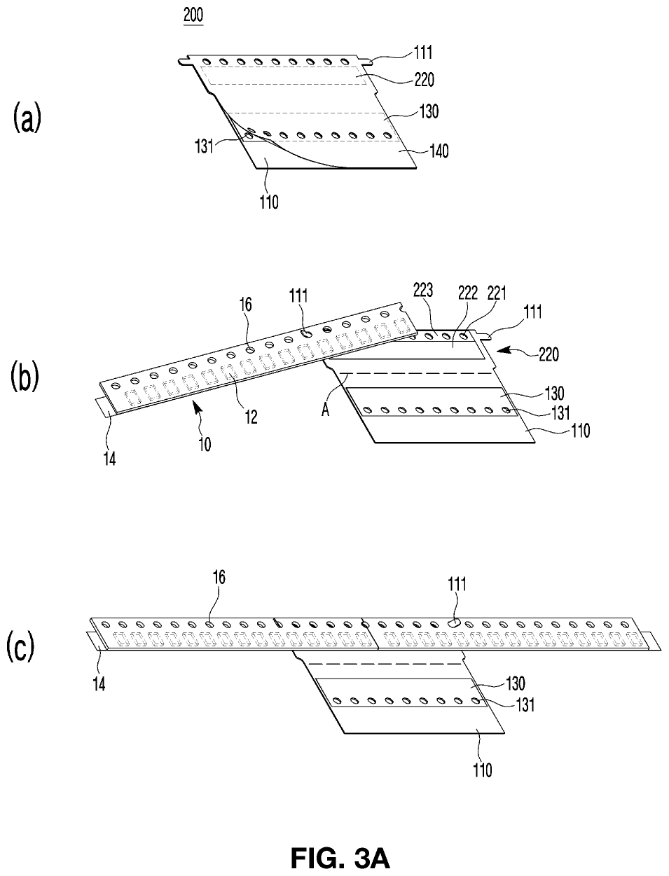

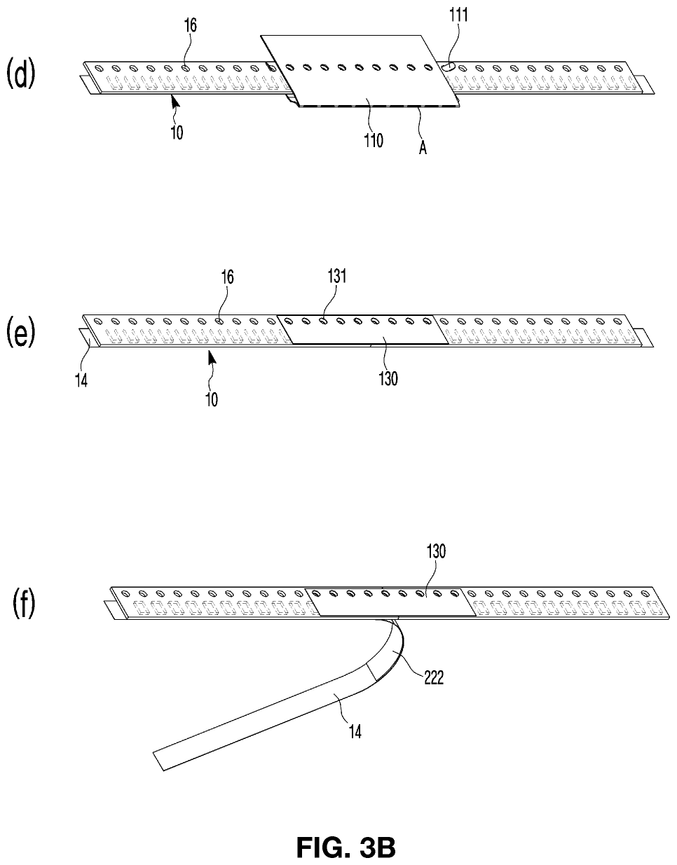

FIGS. 3A and 3B illustrate processes of splicing feeding tapes by a connection jig tape according to a second embodiment of the disclosure. Below, alternative embodiments of the disclosure will be described with reference to the accompanying drawings. In the alternative embodiments, elements indicated by the same reference numerals as those of the first embodiment are configured to have the same functions, and therefore the following descriptions will be made focusing on differences while avoiding repetitive descriptions.

Referring to (a) of FIG. 3A, a connection jig tape 200 according to the second embodiment of the disclosure includes a base tape 110, a first splicing tape 220 and a second splicing tape 130 disposed on the base tape 110 and spaced apart from each other, and a top tape 140 disposed on the first splicing tape 120 and the second splicing tape 130.

The second embodiment is different from the first embodiment shown in FIG. 2 in that the first splicing tape 220 is formed to have the same shape as the second splicing tape 130, and the position holding holes 221 provided in the first splicing tape 220 and the position holding holes 131 provided in the second splicing tape 130 are symmetrically positioned with respect to the folding line A given in the base tape 110.

In other words, unlike the first embodiment where the first splicing tape 220 includes only a first member 222 corresponding to the protection tape 14, the first splicing tape 220 further includes a second member formed with the position holding holes 221 corresponding to the transfer holes 16 of the feeding tape 10 in the state that the projections 111 are inserted in the transfer holes 16. Here, the first member 222 and the second member 223 may be separated from each other or may be connected to be cuttable.

Further, the second splicing tape 130 is formed to have a shame corresponding to the first splicing tape 220. In other words, in the state that the base tape 110 is folded as shown in (d) of FIG. 3B after the projections 111 are inserted in transfer holes 16, the second splicing tape 130 is formed include a third member corresponding to the protection tape 14 and a fourth member formed with the position holding holes 131 corresponding to the transfer holes 16 of the feeding tape 10. Here, the third member and the fourth member are formed as a single body because there are no needs of separating them.

With this configuration, a contact area between the first splicing tape 220 and the feeding tape 10 is larger than that of the first embodiment, thereby having an advantage of more firmly maintaining the spliced state.

Descriptions about (b) and (f) shown in FIGS. 3A and 3B will be omitted because the descriptions made with reference to FIGS. 2A and 2B are equally applicable to the processes of FIGS. 3A and 3B except the foregoing differences. However, when the protection tape 14 is removed in (f) of FIG. 3B, there is a difference in that the first member 222 and the second member 223 of the first splicing tape 220 are separated and thus only the first member 222 is removed along with the protection tape 14.

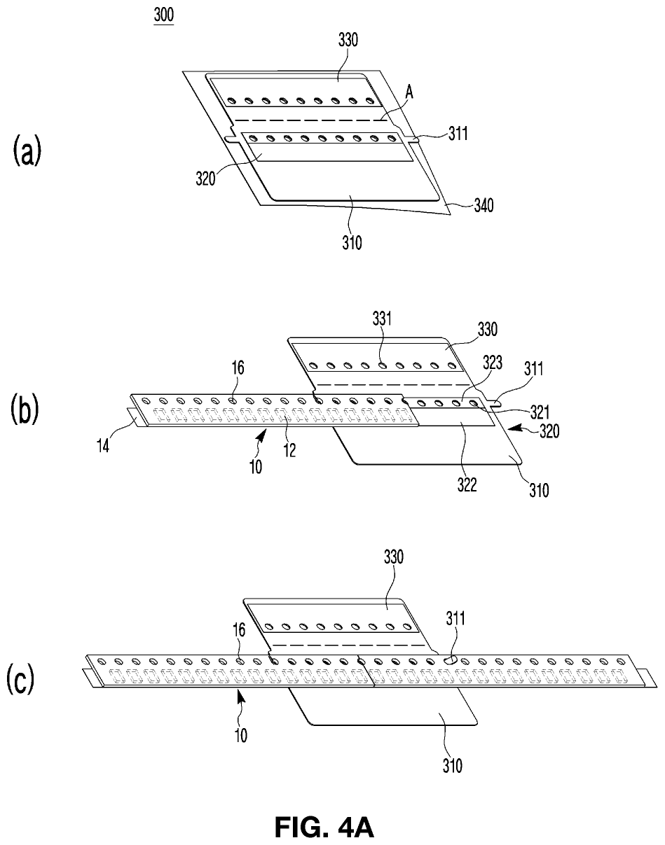

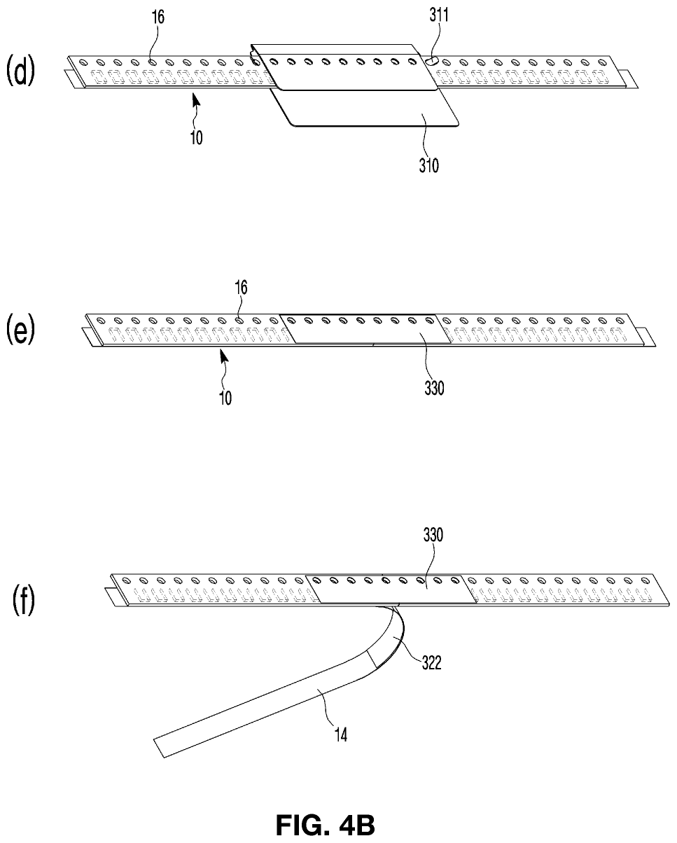

FIGS. 4A and 4B illustrate processes of splicing feeding tapes by a connection jig tape according to a third embodiment of the disclosure.

First, in comparison between the second embodiment and the third embodiment of the disclosure shown in (a) of FIG. 4A, projections 311 provided at opposite sides of a base tape 310 is changed in position from an edge portion to a center portion, and thus a first splicing tape 320 positioned adjacent to the projections 311 and a second splicing tape 330 symmetrical with reference to the folding line A are changed in positions.

In other words, in the first splicing tape 320 including a first member 322 and a second member 323, the second member 323 and the projections 311 are positioned in a straight line, so that the transfer holes 16 and a position holding holes 321 can be arranged to be aligned with each other after the projections 311 are inserted in the transfer holes 16, and therefore position holding holes 331 of the second splicing tape 330 can be arranged line-symmetrically to the position holding holes 321 of the first splicing tape 320.

As shown in (b) of FIG. 4A, such changed position of the projections 311 causes a portion of the transfer holes 16 to be arranged adjacent to the folding line A when the feeding tape 10 is put on the projections 311.

The descriptions made with reference to FIGS. 3A and 3B are equally applicable to the processes shown in FIGS. 4A and 4B except the foregoing differences. In other words, the projections 311 are provisionally held as inserted in the transfer holes 16, and then the base tape 310 is folded with respect to the folding line A, so that the first splicing tape 320 and the second splicing tape 330 can be respectively positioned and fixed on both sides of end portions of the two feeding tapes 10. In this state, parts for surface mounting work are feedable. Then, the parts are fed while the protection tape 14 and the first member 222 on the protection tape 14 are being removed.

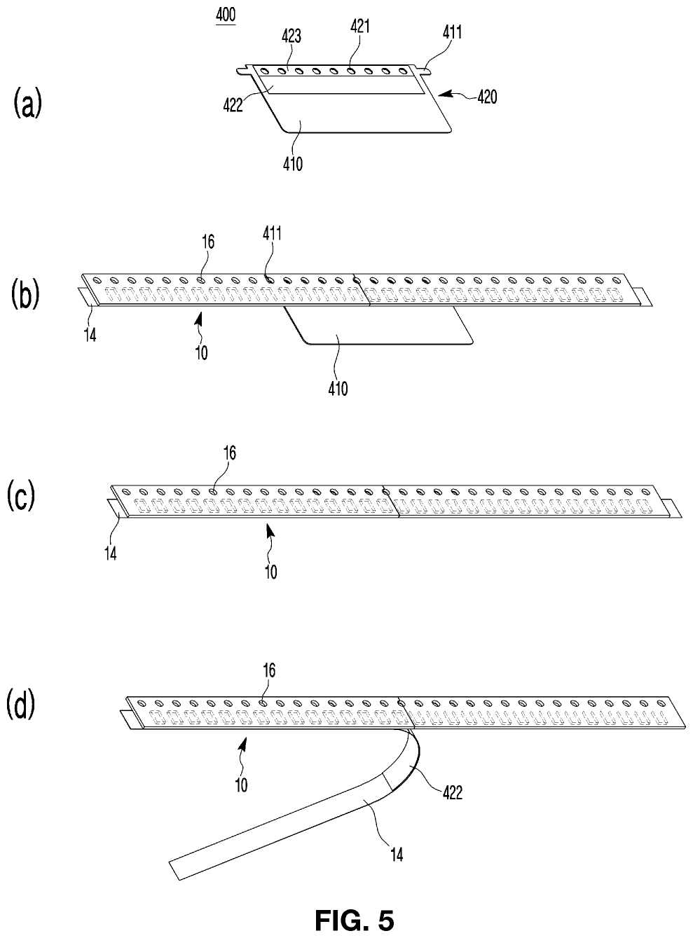

FIG. 5 illustrates processes of splicing feeding tapes by a connection jig tape according to a fourth embodiment of the disclosure.

Unlike the embodiments of FIGS. 3 and 4, a base tape 410 according to the fourth embodiment shown in FIG. 5 is not formed with a folding line in, but includes only a first splicing tape 420, thereby splicing the feeding tapes 10 together by a simpler structure.

In other words, the first splicing tape 420 including a first member 422 and a second member 423 is provided on the base tape 410 in (a) of FIG. 5, and then the projections 411 are inserted in the transfer holes 16 in (b), thereby holding the positions of the feeding tapes 10. Then, the base tape 410 is removed in (C), and thus the two feeding tapes 10 are spliced together by the first splicing tape 420. Next, parts are fed while the protection tape 14 and the first member 422 on the protection tape 14 are being removed.

However, according to this embodiment, splicing work may be performed by previously connecting one sides of the feeding tapes 10 with a connection clip (not shown), and then placing the first splicing tape 420 on the other sides of the feeding tapes 10.

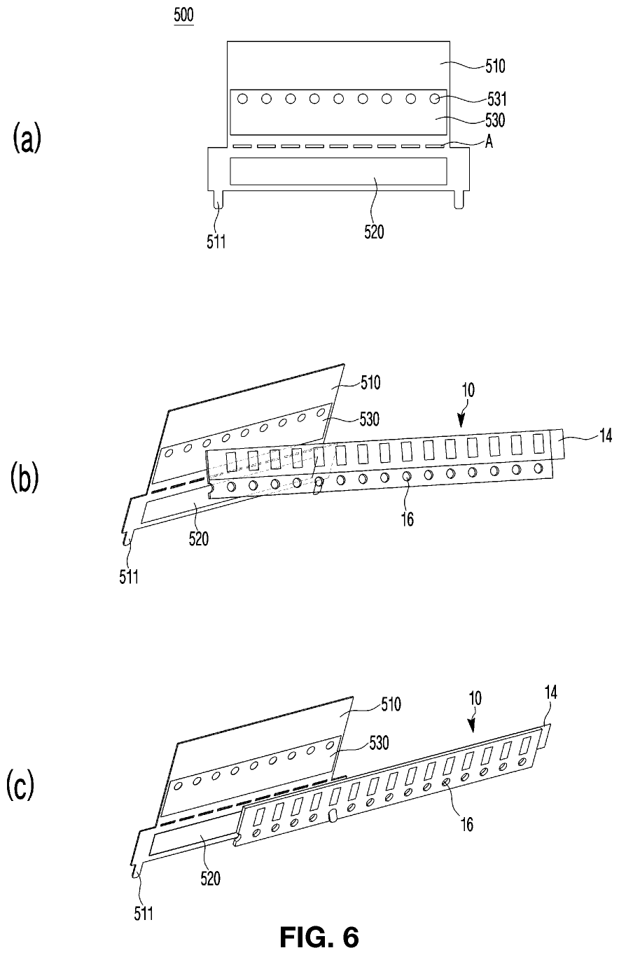

FIG. 6 illustrates processes of splicing feeding tapes by a connection jig tape according to a fifth embodiment of the disclosure.

The fifth embodiment shown in FIG. 6 is different from the first to fourth embodiments in the protruding directions of the projections 111, 311 and 411.

In other words, the projections 111, 311 and 411 according to the first to fourth embodiments are formed protruding from the opposite sides, but two projections 511 according to the fifth embodiment are formed protruding from one side and spaced apart at left and right portions so as to be inserted in the respective feeding tapes 10.

First, referring to (a) in FIG. 6, a connection jig tape 500 according to the fifth embodiment of the disclosure includes a base tape 510, and a first splicing tape 520 and a second splicing tape 530 disposed on the base tape 510 and spaced apart from each other.

Here, two projections 511 protrude from a lower side of the base tape 510 as being spaced apart from each other, in which the projections 511 are inserted in the transfer holes formed in the feeding tape 10 and thus their fixed positions are maintained when the feeding tapes 10 can be connected by the first splicing tape 520. The second splicing tape 530 is formed with position holding holes 531 corresponding to the transfer holes 16 of the feeding tape 10.

Then, as shown in (b), one projection 511 of the foregoing connection jig tape 500 according to the fifth embodiment of the disclosure is inserted in one transfer hole 16 of the feeding tapes 10 to be spliced together.

Next, as shown in (c), when one of the feeding tapes 10 put on and fixed to the projection 511 of the base tape 510, the first splicing tape 520 is positioned on the bottom of the feeding tape 10.

Then, although it is not illustrated, like the method of FIG. 2B, the feeding tape 10 is put on the other projection 511 of the base tape 510, so that the two feeding tapes 10 can be arranged in a straight line while being placed in exact positions to be spliced together by the base tape 110. The second splicing tape 530 is folded to meet the first splicing tape 520 with respect to the folding line A, and the base tape 510 is removed, thereby splicing the two feeding tapes 10 through the first splicing tape 520 and then feeding parts while removing the protection tape 14.

The projections 511 according to the fifth embodiment may be used instead of the projections 111, 311 and 411 according to the first to fourth embodiments.

Meanwhile, the projections provided in the base tape according to the foregoing embodiments of the disclosure are formed in a lengthwise direction (i.e. a y-axis direction) or a widthwise direction (i.e. an x-axis direction) along the plane of the flat base tape, but not limited thereto. Alternatively, the projections may be formed protruding in a perpendicular direction (i.e. a z-axis direction) to the plane of the flat base tape and inserted in the transfer holes of the respective feeding tapes. Such projections oriented in the z-axis direction may be formed by making the projections protrude from the flat base tape in the lengthwise or widthwise direction and then bending or deep-drawing them in the z-axis direction.

As described above, according to various embodiments of the disclosure, the feeding tapes are quickly placed in a fixed position and then spliced together by a simple structure without any separate tool as the projections provided in the base tape are inserted in the transfer holes of the feeding tape. To this end, one side of the first splicing tape or the first and second splicing tapes positioned on the base tape needs to be detachably adhered to the base tape, and the other side of the first splicing tape or the second splicing tape is formed with the adhesive layer to be adhered to the feeding tape.

According to the disclosure, the projections to be inserted in the transfer holes of the respective feeding tapes are provided on the opposite sides of the base tape, thereby having an effect on easily and quickly splicing the feeding tapes together without using any separate tool.

Further, according to the disclosure, the splicing tapes are adhered to the opposite sides at the end portions of the feeding tapes, thereby having an effect on improving exact positioning in a splicing process.

Further, according to the disclosure, there is provided a connection jig tape which can easily splice the feeding tapes together without using any separate tool, thereby having an effect on lowering production costs.

The foregoing embodiments are merely examples of the present inventive concept, and it will be appreciated by those skilled in the art that various modifications, changes and alternatives can be made in these embodiments without departing from the essential features of the invention. Therefore, the embodiments and accompanying drawings of the disclosure are to not limit but describe the present inventive concept, and the scope of the present inventive concept is not restricted by such embodiments and accompanying drawings. The scope of the disclosure should be interpreted by the appended claims, and all technical concept within the same scope should be construed as being included in the scope of the disclosure.

What is claimed is:

1. A connection jig tape for splicing end portions of feeding tapes together, the feeding tape comprising accommodating spaces formed to accommodate electronic parts therein, a protection tape disposed on the electronic parts, and a plurality of transfer holes formed at one side thereof,
the connection jig comprising:
a base tape comprising projections formed to protrude from opposite sides thereof or at least two projections formed to protrude from one side thereof and spaced apart from each other to be inserted in the transfer holes of the respective feeding tapes to be spliced together; and
a first splicing tape disposed on the base tape.

2. The connection jig tape according to claim 1, wherein the first splicing tape comprises a first member corresponding to the protection tape while the projections are inserted in the transfer holes.

3. The connection jig tape according to claim 2, wherein
the first splicing tape further comprises a second member formed with first position holding holes corresponding to the transfer holes of the feeding tape, and
the first member and the second member are separated from each other or connected to be cuttable.

4. The connection jig tape according to claim 3, wherein
the base tape comprises a folding line, and
the connection jig further comprises a second splicing tape formed with a second position holding hole positioned line-symmetrically to the first position holding hole with respect to the folding line.

5. The connection jig tape according to claim 4, wherein the second splicing tape comprises a third member correspond ding to the protection tape, and a fourth member formed with the second position holding hole corresponding to the transfer hole of the feeding tape, in the state that the projection is inserted in the transfer hole and the base tape is folded with respect to the folding line.

6. The connection jig tape according to claim 5, further comprising a top tape disposed on the first splicing tape or the second splicing tape.

7. The connection jig tape according to claim 6, wherein
one side of the first splicing tape or the second splicing tape is detachably adhered to the base tape, and the other side of the first splicing tape or the second splicing tape is formed with an adhesive layer.

8. The connection jig tape according to claim 1, wherein the base tape at least partially comprises an elastic member.

9. The connection jig tape according to claim 2, wherein the base tape at least partially comprises an elastic member.

10. The connection jig tape according to claim 3, wherein the base tape at least partially comprises an elastic member.

11. The connection jig tape according to claim 4, wherein the base tape at least partially comprises an elastic member.

12. The connection jig tape according to claim 5, wherein the base tape at least partially comprises an elastic member.

13. The connection jig tape according to claim 6, wherein the base tape at least partially comprises an elastic member.

14. The connection jig tape according to claim 7, wherein the base tape at least partially comprises an elastic member.
